(19) United States
(12) Patent Application Publication
(10) Pub. No.: US 2018/0080117 A1
(43) Pub. Date: Mar. 22, 2018

(54) Vacuum Evaporation Coating Equipment

(71) Applicants: BOE Technology Group Co., Ltd., Beijing (CN); Hefei BOE Optoelectronics Technology Co., Ltd., Hefei (CN)

(72) Inventors: Hui An, Beijing (CN); Biliang Dong, Beijing (CN); Xianxue Duan, Beijing (CN)

(73) Assignees: BOE Technology Group Co., Ltd., Beijing (CN); Hefei BOE Optoelectronics Technology Co., Ltd., Hefei (CN)

(21) Appl. No.: 15/521,429

(22) PCT Filed: Sep. 23, 2016
(86) PCT No.: PCT/CN2016/099916

§ 371 Date: Apr. 24, 2017

(30) Foreign Application Priority Data
Jan. 18, 2016 (CN) 201620051276.7

(51) Int. Cl. C23C 14/24; C23C 14/04

(52) U.S. Cl. CPC C23C 14/24; C23C 14/042

(57) ABSTRACT

A vacuum evaporation coating equipment, includes an evaporation source; a carrier for mounting a substrate to be coated; a plurality of masks connected to each other which are disposed between the evaporation source and the carrier; and a driving mechanism. The plurality of masks form at least two sets of correction masks; a driving mechanism is connected to each set of the correction masks and configured for driving one of the at least two sets of correction masks to be located within an evaporation stroke of material of the evaporation source.

### TECHNICAL FIELD

Embodiments of the disclosure relate to a technical field of manufacturing electronic devices, especially relate to a vacuum evaporation coating equipment.

### BACKGROUND

Vacuum evaporation coating equipment is widely used in manufacturing integrated circuits, LEDs (light-emitting diode) and other semiconductor wafer chips, and the common mode is electron beam heating.

In the multi-layer film coating process, the corresponding thickness of different layers is different. For example, in the case of metal electrode preparation, for example, the layer with an electrical conductivity property in the metal electrode film has a maximum thickness (about several micrometers), and the layer with function of adhesion, block, or ohmic contact is relatively thinner (about dozens of nanometers). The difference between the thicknesses of the two layers may be up to tens of times or even hundreds of times, such a large thickness difference would cause the difference in fall height of the evaporated liquid during the evaporation coating process for fabricating the respective two layers. As a result, the impact of the evaporation angle on fabricating the two layers is different, and it is difficult to make all the layers uniform under high benchmark conditions, while sharing the same correction mask.

Therefore, in prior art, for the various types of evaporation sources in the cavity of the vacuum evaporation coating equipment, it is difficult to ensure that all the layers simultaneously satisfy high uniformity benchmark, by using only one correction mask.

### SUMMARY

The object of the disclosure is to provide a vacuum evaporation coating equipment, and solve the problem that high uniformity of all the layers cannot be satisfied while using a single correction mask in a plurality of evaporation sources in prior art.

A vacuum evaporation coating equipment, comprising: an evaporation source and a carrier for mounting a substrate to be coated, wherein the vacuum evaporation coating equipment further comprises: a plurality of masks connected to each other, which are disposed between the evaporation source and the carrier, wherein a plurality of masks form at least two sets of correction masks; a driving mechanism for driving the correction mask, wherein the driving mechanism is connected to each set of the correction masks.

### BRIEF DESCRIPTION OF THE DRAWINGS

In order to clearly illustrate the technical solution of the embodiments of the disclosure, the drawings of the embodiments will be briefly described in the following; it is obvious that the described drawings are only related to some embodiments of the disclosure and thus are not limitative of the disclosure.

FIG. 1 schematically illustrates a principle structure diagram of a vacuum evaporation coating equipment;

FIG. 2 schematically illustrates a simplified three-dimensional structure diagram of a correction mask disposed in the vacuum evaporation coating equipment according to an embodiment of the disclosure;

FIG. 3 schematically illustrates a cross-section view of a correction mask disposed in the vacuum evaporation coating equipment according to an embodiment of the disclosure;

FIG. 4 schematically illustrates a cross-section view of a correction mask disposed in the vacuum evaporation coating equipment according to another embodiment of the disclosure;

FIGS. 5a and 5b schematically illustrate an evaporation stroke range and an evaporation angle respectively, while an evaporation source is at different levels.

### DETAILED DESCRIPTION

In order to make objects, technical details and advantages of the embodiments of the disclosure apparent, the technical solutions of the embodiments will be described in a clearly and fully understandable way in connection with the drawings related to the embodiments of the disclosure. Apparently, the described embodiments are just a part but not all of the embodiments of the disclosure. Based on the described embodiments herein, those skilled in the art can obtain other embodiment(s), without any inventive work, which should be within the scope of the disclosure

FIG. 1 schematically illustrates an electron beam vacuum evaporation coating equipment. An evaporation source 01 in solid state is heated by electron beam and heated to be in molten and liquid state. After reaching to a boiling point of the evaporation material, the evaporation source 01 is evaporated, the gaseous molecules are volatilized to the top of a cavity and condensed rapidly to form a film while encountering a substrate 03 at a lower temperature. In order to ensure the uniformity of the film formed on the substrate, a supporter of the substrate 03 is designed to be an umbrella shape and rotated at a constant speed, and the evaporation source 01 is located near the spherical center of the spherical surface where the umbrella is located. Different evaporation source materials are placed in different crucibles, and the crucibles are switchable by rotation. In order to further ensure the uniformity of the film at different locations on the substrate, a correction mask 02 having a thinner thickness and a specific shape is commonly disposed between the evaporation source 01 and the substrate 03, and a partial evaporation stroke of the source material in the space is selectively shielded by the correction mask 02, so the deposition amount at locations where the thicker film may be formed is reduced.

An embodiment of the disclosure provides a vacuum evaporation coating equipment, which comprises an evaporation source and a carrier for mounting a substrate to be coated, herein, the vacuum evaporation coating equipment further comprises: a plurality of masks connected to each other and form at least two sets of correction masks, the plurality of masks are disposed between the evaporation source and the carrier; and a driving mechanism for driving the correction masks, the driving mechanism is connected to each set of the correction masks.

In the vacuum evaporation coating equipment provided in the present embodiment, by increasing the number of the correction masks, different sets of the correction masks can be selected for different films in the evaporation stroke of the evaporation source, so as to ensure the uniformity of the different films.

In the vacuum evaporation coating equipment provided in the present embodiment, when the first set of correction masks is located within the evaporation stroke of the evaporation source material, other sets of correction masks are perpendicular to an evaporation liquid level of the evaporation source, or located on the other side facing the evaporation source with respect to the first set of correction masks. With this arrangement, the current evaporation coating process will not be affected by other sets of correction masks, while the first set of correction masks is used for the current evaporation coating process.

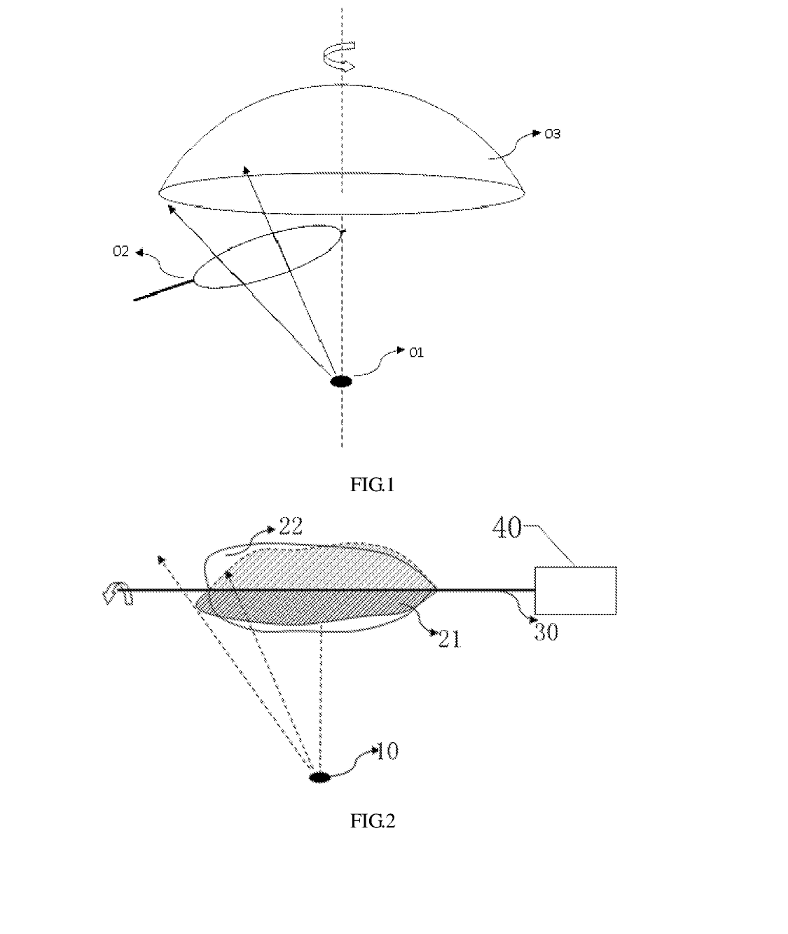

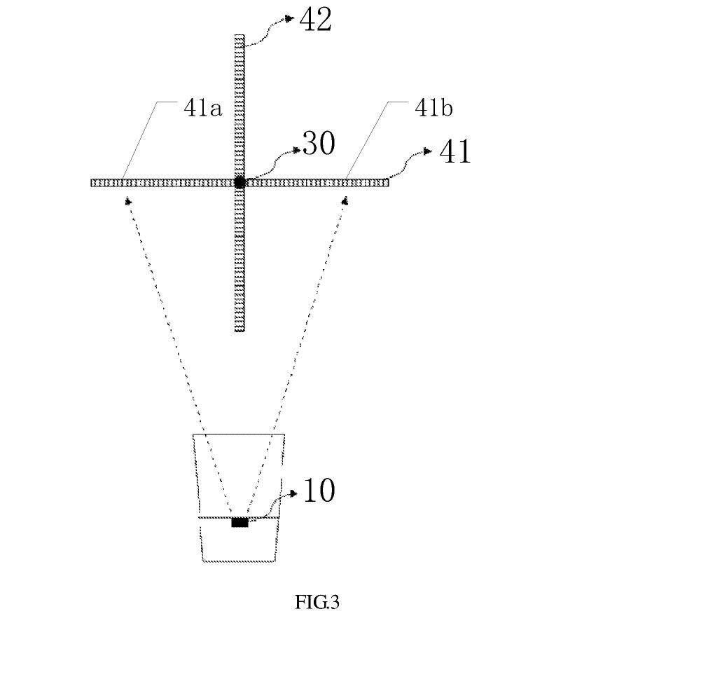

FIG. 2 schematically illustrates a simplified three-dimensional structure diagram of a correction mask disposed in the vacuum evaporation coating equipment according to a first embodiment of the disclosure. FIG. 3 schematically illustrates a cross-section view of a correction mask disposed in the vacuum evaporation coating equipment of FIG. 2. As illustrated in FIG. 2 and FIG. 3, in first embodiment, the vacuum evaporation coating equipment comprises an evaporation source 10, a carrier (not shown) for mounting a substrate to be coated, and two masks 41 and 42 cross-connected to each other, herein the mask 41 is disposed above the evaporation source 10, and between the evaporation source 10 and the carrier for mounting the substrate to be coated.

As illustrated in FIG. 2 and FIG. 3, two masks 41 and 42 are fixedly connected to each other at their respective middle positions, a single mask forms a set of correction mask. Therefore, the present embodiment comprises a first set of correction mask 41 and a second set of correction mask 42, the first set of correction mask and the second set of correction mask are perpendicular to each other, and are cross-connected to each other at their respective middle positions.

The vacuum evaporation coating equipment further comprises a driving mechanism which is connected to both the first set of connection mask and the second set of connection mask, for example, the driving mechanism comprises: a driving motor 40; a support rod 30 connected to an output shaft of the driving motor 40. The first set of the correction mask 41 and the second set of correction mask 42 are fixedly connected to the support rod 30, respectively.

The support rod 30 is connected to and penetrated into the middle of each of the masks. As illustrated in FIG. 2, in the first embodiment, the support rod 30 is fixedly connected to the middle of the first set of the correction mask 41 and the middle of the second set of the correction mask 42 respectively, so that the first set of the correction mask 41 and the second set of the correction mask 42, which are perpendicular to each other, are cross-connected to each other at their respective middle position. Gears may be disposed on both ends of the support rod 30, so that the support rod 30 is engaged with the driving motor through the gears. This arrangement is simple and firm, and the correction masks are rotated through combination of multiple sets of gears, so the precise control can be achieved.

Additionally, in order to achieve the above connection between the first set of correction mask 41 and the second set of correction mask 42, as an example, an opening is formed in the middle of one set of correction mask, the other set of the correction mask is inserted vertically into the opening, and the support rod 30 is fixedly connected to both sets of the correction masks respectively, so that the first set of the correction mask 41 and the second set of the correction mask 42 are cross-connected at their respective middle position. As another example, the first set of the correction mask 41 and the second set of the correction mask 42 respectively comprises two portions, for example, as illustrated in FIG. 3, the first set of the correction mask 41 comprises a first portion 41a and a second portion 41b, through holes which are configured to be fixedly connected to the support rod 30 are formed in respective opposing ends of the first portion 41a and the second portion 41b, and the first portion 41a and the second portion 41b are located in the same plane, that is, an angle between the two portions is 180 degrees, thus a plate-shape first correction mask 41 or a plate-shape second correction mask 42 is formed.

In at least some of embodiments, the first set of correction mask 41 and the second set of correction mask 42 are made of a heat-resisting material, and the thickness is required to be as thin as possible in condition of having enough mechanical strength. Specific materials and structures of correction masks are not described in detail herein.

During the operation of the vacuum evaporation coating equipment described in the first embodiment, the first set of the correction mask 41 and the second set of the correction mask 42 are perpendicular to each other, when the first set of the correction mask 41 is configured to shield the evaporation source 10 during the current evaporation coating process, the correction mask 41 is parallel to the evaporation liquid level of the evaporation source 10, and the second set of the correction mask 42 is perpendicular to the evaporation liquid level. In this case, the region which the evaporation stroke of the evaporation source 10 is shielded by the second set of the correction mask 42 has a smaller area and is located within the shielding region of the first set of correction mask 41, so the shielding function of the second set of the correction mask 42 is relatively weak.

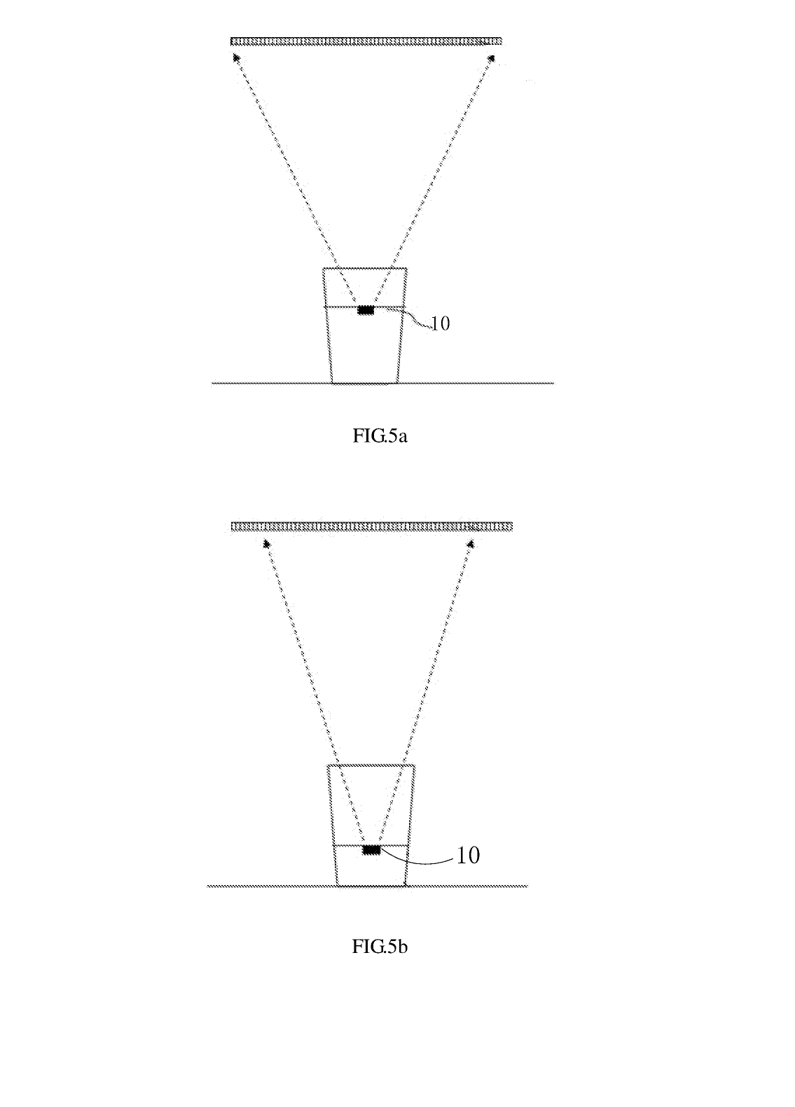

As illustrated in FIG. 5a and FIG. 5b, during the same evaporation coating process, with the consumption of the evaporation material in the evaporation source 10, a evaporation angle is changed. The evaporation angle is changed greatly, while a height of liquid level in the evaporation source 10 is changed greatly. When the height of liquid level decreases, the evaporation angle will be reduced, and the area which the vapor stroke is shielded by the set of the correction mask will be reduced. Therefore, during the fabrication of the same electronic device, when the films to be prepared have different thicknesses, and the difference between the thickness of films is larger, such as tens of times or even hundreds of times, there will be a difference in consumption of the evaporation source between the respective evaporation coating processes, which in turns results in a difference in a decrease of liquid level height during the evaporation coating process, and an impact of the evaporation angle on films is different, so it is difficult to ensure the uniformity of all the films under high benchmark conditions by using a single correction mask.

However, in the vacuum evaporation coating equipment provided in the present embodiment, during the entire evaporation coating process for preparing relatively thinner films (tens of nanometers, hundreds of nanometers, etc.), the consumption of evaporation source is small, and the change in liquid level height is tiny (almost no change), thus, a single set of correction mask is enough to complete the entire evaporation coating process, in the case of ensuring that the initial liquid level of the evaporation source is uniform. Moreover, during the entire evaporation coating process for preparing relatively thicker layers (several micrometers etc.), the consumption of evaporation source is large, the height of liquid level is decreased greatly, and the evaporation angle is changed greatly, in order to ensure uniformity of the films, two sets of correction masks may be used in the entire evaporation coating process.

When the vacuum evaporation coating equipment provided in the first embodiment is adopted, the number of evaporation sources is at least two, the first set of correction mask and the second set of correction mask may respectively correspond to the evaporation coating process of different evaporation sources. For example, when the evaporation coating process for forming the film is achieved by using a first evaporation source and the first set of correction mask and is completed, the second set of correction mask is driven by a driving mechanism and is rotated to correspond to a second evaporation source, and the second evaporation source and the second set of correction mask will be used in another evaporation coating process for forming another film.

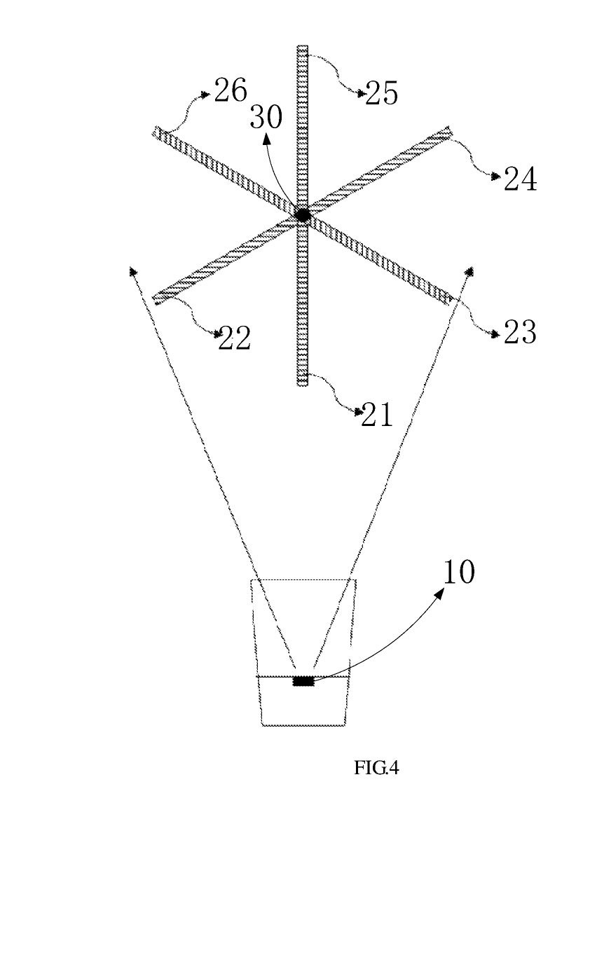

Another vacuum evaporation coating equipment is provided in the second embodiment of the disclosure. FIG. 4 schematically illustrates a cross-section view of the vacuum evaporation coating equipment according to the second embodiment of the disclosure. The vacuum evaporation coating equipment comprises an evaporation source 10, a carrier (not shown) for mounting a substrate to be coated, and a plurality of masks 21, 22, 23, 24, 25 and 26 connected to each other, herein a plurality of masks are disposed above the evaporation source 10 and are located between the evaporation source 10 and the carrier for mounting the substrate to be coated.

As illustrated in FIG. 4, six masks 21, 22, 23, 24, 25, 26 are respectively extended in different directions, and they are connected together at one end, an angle between two adjacent masks is less than or equal to 180 degrees, a single set of correction mask is constituted by a combination with one of the masks and another mask.

The vacuum evaporation coating equipment further comprises a driving mechanism which is connected to each of masks, for example, the driving mechanism comprises: a driving motor (not shown); a support rod 30 connected to an output shaft of the driving motor, herein one end of each mask is fixedly connected to the support rod 30.

As illustrated in FIG. 4, in second embodiment, the number of masks is six, and an angle between the two adjacent masks is 60 degrees, so that the six masks are arranged evenly around the support rod 30 above the evaporation source 10. According to this arrangement, when a first mask 21 is vertically downwardly extended, a second mask 22 and a third mask 23 located on both sides of the first mask 21 form a first set of correction masks, the first set of correction masks is located within an evaporation stroke of material of the evaporation source 10, other sets of correction masks are perpendicular to an evaporation liquid level of the evaporation source 10 or located on the other side facing the evaporation source with respect to the first set of correction masks. When a plurality of masks are driven to rotate by the driving mechanism, such as a clockwise rotation with 60 degrees, the third mask 23 is vertically downward, the first mask 21 and a fourth mask 24 on both sides of the third mask 23 form a second set of correction masks, and the second set of correction masks are located within the evaporation stroke of material of the evaporation source 10. Based on this principle, among the first mask 21, the second mask 22, the third mask 23, the fourth mask 24, the fifth mask 25 and the sixth mask 26, two masks which have an angle of 120 degrees therebetween are combined and form a set of correction masks for shielding in the evaporation coating process. Different sets of correction masks can be rotated through the driving mechanism and used in different evaporation coating processes.

During the operation of the vacuum evaporation coating equipment provided in the second embodiment, when the first set of correction masks (for example, the combination of the second mask 22 and the third mask 23) is used for shielding in the current evaporation coating process, that is, it is located within a shielding scope of the evaporation stroke of the evaporation source 10, the first mask 21 and the fifth mask 25 are arranged vertically, and the fourth mask 24 and the sixth mask 26 are located on the other side facing the evaporation source 10 (i.e., on back side of the first set of the correction mask with respect to the evaporation source 10). In addition to the second mask 22 and the third mask 23, the effective projection area of other masks relative to the evaporation source 10 is relatively small, and is shielded by the two masks 22, 23 of the first set of correction masks, so the shielding effect on the evaporation source 10 is relatively weak. Similarly, After all the correction masks are rotated by the driving mechanism, other sets of correction masks may be rotated to be located within the shielding scope of the evaporation stroke of the evaporation source 10 and may be also used for controlling the thickness of layers in the evaporation coating process.

By using the correction masks described above, during the entire evaporation coating process for preparing relatively thinner films (tens of nanometers, hundreds of nanometers, etc.), the consumption of evaporation source is small, and the change in liquid level height is tiny (almost no change), thus, a single set of correction mask is enough to complete the entire evaporation coating process, in the case of ensuring that the initial liquid level of the evaporation source is uniform. Moreover, during the entire evaporation coating process for preparing relatively thicker layers (several micrometers etc.), the consumption of evaporation source is large, the height of liquid level is decreased greatly, and the evaporation angle is changed greatly, in order to ensure uniformity of the films, three sets of correction masks may be used in the entire evaporation coating process.

In at least some of embodiments, six masks form six sets of correction masks respectively. Thus, there may be six evaporation sources, different sets of correction masks may respectively correspond to different evaporation coating processes of different evaporation sources. When an evaporation coating process is achieved by a first evaporation source and the first set of correction mask and is completed, other sets of correction masks are driven by a driving mechanism and will be used in another evaporation coating process.

In addition, in the above-mentioned plurality of sets of correction masks, for each set of correction masks, when a shape of one mask comprised in a set of correction masks is rationally designed, it is possible to adjust thickness uniformity of films evaporated by the evaporation source by optimizing the shape of another mask. Therefore, by using the vacuum evaporation coating equipment provided in the second embodiment, the thickness uniformity between the target films which are formed on an umbrella-shaped substrate by using five or six different kinds of evaporation sources can be ensured.

According to the principles provided in the disclosure, the arrangement and number of the correction masks are not limited to those shown in FIG. 4, for example, the number of sets of correction masks can be equal to or more than four, and the angle between adjacent masks is adjustable according to the specific process requirements.

Furthermore, according to the second embodiment, the first mask 21 and the fifth mask 25 are located in the same plane, the second mask 22 and the fourth mask 24 are located in the same plane, and the third mask 23 and the sixth mask 26 are located in the same plane, so the above two masks which are located in the same plane may be an integral structure and form a structure in which three masks are cross-connected at their respective middle position.

According to the vacuum evaporation coating equipment provided in the present embodiment, different correction masks can be switched during the evaporation coating process in which the same evaporation source is used, or different correction masks corresponds to different evaporation sources. Compared with the same correction mask used in prior art, the structure provided in the present embodiment is more freedom in keeping the uniformity of the plurality of films.

What is described above is related to the illustrative embodiments of the disclosure only and not limitative to the scope of the disclosure; the scopes of the disclosure are defined by the accompanying claims.

The present application claims the priority of Chinese patent application No. 201620051276.7 filed on Jan. 18, 2016, the disclosure of which is hereby incorporated by reference herein in its entirety.

1. A vacuum evaporation coating equipment, comprising: an evaporation source and a carrier for mounting a substrate to be coated, wherein the vacuum evaporation coating equipment further comprises:
a plurality of masks connected to each other, which are disposed between the evaporation source and the carrier, wherein a plurality of masks form at least two sets of correction masks;
a driving mechanism for driving the correction mask, wherein the driving mechanism is connected to each set of the correction masks.

2. The vacuum evaporation coating equipment according to claim 1, wherein the driving mechanism comprises:
a driving motor;
a support rod connected to an output shaft of the driving motor, wherein each set of the correction masks is fixedly connected to the support rod.

3. The vacuum evaporation coating equipment according to claim 1, wherein the support rod is connected to the middle of each of the masks respectively, and each mask forms a set of correction mask.

4. The vacuum evaporation coating equipment according to claim 3, wherein two adjacent sets of correction masks are intersected each other.

5. The vacuum evaporation coating equipment according to claim 4, wherein a plurality of masks form two sets of correction masks, one set of correction masks is perpendicular to another set of correction masks.

6. The vacuum evaporation coating equipment according to claim 1, wherein a plurality of masks are respectively extended in different directions and are connected together at their respective one ends, an angle between two adjacent masks is less than or equal to 180 degrees.

7. The vacuum evaporation coating equipment according to claim 6, wherein a number of masks is six, and an angle between two adjacent masks is 60 degrees.

8. The vacuum evaporation coating equipment according to claim 7, wherein a first mask of the six masks is vertically downwardly extended, a second mask and a third mask located on both sides of the first mask form a set of correction masks, and the set of correction masks is located within an evaporation stroke of material of the evaporation source.

9. The vacuum evaporation coating equipment according to claim 1, wherein one of sets of correction masks is located within an evaporation stroke of material of the evaporation source.

10. The vacuum evaporation coating equipment according to claim 9, wherein other sets of correction masks are perpendicular to an evaporation liquid level of the evaporation source, or located on a side opposite to the evaporation source with respect to the first set of correction masks.

11. The vacuum evaporation coating equipment according to claim 1, wherein a number of the evaporation sources is at least two, and different sets of correction masks are driven by the driving mechanism to correspond to different evaporation sources.
